(19) United States
(12) Patent Application Publication
(10) Pub. No.: US 2025/0345932 A1
(43) Pub. Date: Nov. 13, 2025

(54) LEARNING PHYSICS-BASED INTERACTIONS FROM DEMONSTRATION

(71) Applicant: Honda Motor Co., Ltd., Tokyo (JP)

(72) Inventors: Tianyu LI, Atlanta, GA (US); Hengbo MA, Mountain View, CA (US); Kwonjoon LEE, Sunnyvale, CA (US)

(21) Appl. No.: 18/984,087

(22) Filed: Dec. 17, 2024

Related U.S. Application Data
(60) Provisional application No. 63/646,499, filed on May 13, 2024.

(51) Int. Cl. B25J 9/16; G05B 13/02; G06F 30/27

(52) U.S. Cl. CPC B25J 9/163; G05B 13/0265; G06F 30/27

(57) ABSTRACT

According to one aspect, learning physics-based interactions from demonstration may include learning a sparse embedded interaction graph from a fully connected graph indicative of an interaction between a first character and a second character based on cross attention between a pose and a current interaction graph and training a policy for controlling interactions between the first character and the second character based on using the sparse embedded interaction graph as a reward.

### CROSS-REFERENCE TO RELATED APPLICATIONS

This application claims the benefit of U.S. Provisional Patent Application, Ser. No. 63/646,499 (Attorney Docket No. H1241156US01) entitled “LEARNING PHYSICS-BASED CHARACTERS INTERACTION FROM HUMAN DEMONSTRATION”, filed on May 13, 2024; the entirety of the above-noted application(s) is incorporated by reference herein.

### BACKGROUND

Life-like interactions between humans and non-humanoid agents are popular in both real-world and virtual applications. Many computer games feature dynamic interactions, such as combat between a playable character and monsters. Similarly, real-world robots, seen as physical embodiments of characters, collaborate to perform tasks beyond the capabilities of a single agent, like lifting heavy objects. Collaborative robots may interact with humans in various scenarios, from manufacturing to healthcare, emphasizing the importance of interactions with non-humanoid agents. Despite its potential impact, much of the existing research has focused on interactions between specific morphologies while leaving the development of a general algorithmic approach for learning interactions between diverse morphologies an open-ended question.

### BRIEF DESCRIPTION

According to one aspect, a system for learning physics-based interactions from demonstration may include a memory and a processor. The memory may store one or more instructions. The processor may execute one or more of the instructions stored on the memory to perform one or more acts, actions, and/or steps. For example, the processor may learn a sparse embedded interaction graph from a fully connected graph indicative of an interaction between a first character and a second character based on cross attention between a pose and a current interaction graph. The processor may train a policy for controlling interactions between the first character and the second character based on using the sparse embedded interaction graph as a reward.

The processor may implement the policy to control an interaction between a first robot and a second robot. The fully connected graph may be indicative of a first pose associated with the first character and a second pose associated with the second character. The cross attention may be between the first pose of the first character or the second pose of the second character and the current interaction graph. The current interaction graph may be derived from the fully connected graph. The processor may generate a pose latent vector based on passing the sparse embedded interaction graph through a graph encoder. The processor may generate a future interaction state for the first character and the second character based on passing the pose latent vector and a first pose associated with the first character through a pose decoder and passing the pose latent vector and a second pose associated with the second character through a second pose decoder. The pose decoder may be trained based on a pre-trained motion variable autoencoder (VAE). The policy may be trained based on a reinforcement learning approach. The training the policy may be based on a physics-based simulation.

According to one aspect, a computer-implemented method for learning physics-based interactions from demonstration may include learning a sparse embedded interaction graph from a fully connected graph indicative of an interaction between a first character and a second character based on cross attention between a pose and a current interaction graph and training a policy for controlling interactions between the first character and the second character based on using the sparse embedded interaction graph as a reward.

The computer-implemented method for learning physics-based interactions from demonstration may include implementing the policy to control an interaction between a first robot and a second robot. The fully connected graph may be indicative of a first pose associated with the first character and a second pose associated with the second character. The cross attention may be between the first pose of the first character or the second pose of the second character and the current interaction graph. The computer-implemented method for learning physics-based interactions from demonstration may include deriving the current interaction graph from the fully connected graph.

According to one aspect, a system for learning physics-based interactions from demonstration may include a processor and a memory. The memory may store one or more instructions. The processor may execute one or more of the instructions stored on the memory to perform one or more acts, actions, and/or steps. For example, the processor may learn a sparse embedded interaction graph from a fully connected graph indicative of an interaction between a first character and a second character based on cross attention between a pose of the first character or a pose of the second character and a current interaction graph. The processor may train a policy for controlling interactions between the first character and the second character based on using the sparse embedded interaction graph as a reward. The processor may implement the policy to control an interaction between a first robot and a second robot.

The fully connected graph may be indicative of a first pose associated with the first character and a second pose associated with the second character. The cross attention may be between the first pose of the first character or the second pose of the second character and the current interaction graph. The current interaction graph may be derived from the fully connected graph. The processor may generate a pose latent vector based on passing the sparse embedded interaction graph through a graph encoder.

### BRIEF DESCRIPTION OF THE DRAWINGS

FIG. 1 is an exemplary component diagram of a system for learning physics-based interactions from demonstration, according to one aspect.

FIG. 2 is an exemplary scenario associated with learning physics-based interactions from demonstration, according to one aspect.

FIG. 3 is an exemplary flow diagram of a computer-implemented method for learning physics-based interactions from demonstration, according to one aspect.

FIG. 4 is an illustration of an example computing environment where one or more of the provisions set forth herein are implemented, according to one aspect.

FIG. 5 is an illustration of an example computer-readable medium or computer-readable device including processor-executable instructions configured to embody one or more of the provisions set forth herein, according to one aspect.

### DETAILED DESCRIPTION

The following includes definitions of selected terms employed herein. The definitions include various examples and/or forms of components that fall within the scope of a term and that may be used for implementation. The examples are not intended to be limiting. Further, one having ordinary skill in the art will appreciate that the components discussed herein, may be combined, omitted, or organized with other components or organized into different architectures.

A “processor”, as used herein, processes signals and performs general computing and arithmetic functions. Signals processed by the processor may include digital signals, data signals, computer instructions, processor instructions, messages, a bit, a bit stream, or other means that may be received, transmitted, and/or detected. Generally, the processor may be a variety of various processors including multiple single and multicore processors and co-processors and other multiple single and multicore processor and co-processor architectures. The processor may include various modules to execute various functions.

A “memory”, as used herein, may include volatile memory and/or non-volatile memory. Non-volatile memory may include, for example, ROM (read only memory), PROM (programmable read only memory), EPROM (erasable PROM), and EEPROM (electrically erasable PROM). Volatile memory may include, for example, RAM (random access memory), synchronous RAM (SRAM), dynamic RAM (DRAM), synchronous DRAM (SDRAM), double data rate SDRAM (DDRSDRAM), and direct RAM bus RAM (DRRAM). The memory may store an operating system that controls or allocates resources of a computing device.

A “disk” or “drive”, as used herein, may be a magnetic disk drive, a solid-state disk drive, a floppy disk drive, a tape drive, a Zip drive, a flash memory card, and/or a memory stick. Furthermore, the disk may be a CD-ROM (compact disk ROM), a CD recordable drive (CD-R drive), a CD rewritable drive (CD-RW drive), and/or a digital video ROM drive (DVD-ROM). The disk may store an operating system that controls or allocates resources of a computing device.

A “bus”, as used herein, refers to an interconnected architecture that is operably connected to other computer components inside a computer or between computers. The bus may transfer data between the computer components. The bus may be a memory bus, a memory controller, a peripheral bus, an external bus, a crossbar switch, and/or a local bus, among others. The bus may also be a vehicle bus that interconnects components inside a vehicle using protocols such as Media Oriented Systems Transport (MOST), Controller Area network (CAN), Local Interconnect Network (LIN), among others.

A “database”, as used herein, may refer to a table, a set of tables, and a set of data stores (e.g., disks) and/or methods for accessing and/or manipulating those data stores.

An “operable connection”, or a connection by which entities are “operably connected”, is one in which signals, physical communications, and/or logical communications may be sent and/or received. An operable connection may include a wireless interface, a physical interface, a data interface, and/or an electrical interface.

A “computer communication”, as used herein, refers to a communication between two or more computing devices (e.g., computer, personal digital assistant, cellular telephone, network device) and may be, for example, a network transfer, a file transfer, an applet transfer, an email, a hypertext transfer protocol (HTTP) transfer, and so on. A computer communication may occur across, for example, a wireless system (e.g., IEEE 802.11), an Ethernet system (e.g., IEEE 802.3), a token ring system (e.g., IEEE 802.5), a local area network (LAN), a wide area network (WAN), a point-to-point system, a circuit switching system, a packet switching system, among others.

A “mobile device”, as used herein, may be a computing device typically having a display screen with a user input (e.g., touch, keyboard) and a processor for computing. Mobile devices include handheld devices, portable electronic devices, smart phones, laptops, tablets, and e-readers.

A “robot”, as used herein, may be a machine, such as one programmable by a computer, and capable of carrying out a complex series of actions automatically. A robot may be guided by an external control device or the control may be embedded within a controller. It will be appreciated that a robot may be designed to perform a task with no regard to appearance. Therefore, a ‘robot’ may include a machine which does not necessarily resemble a human, including a vehicle, a device, a flying robot, a manipulator, a robotic arm, etc.

A “robot system”, as used herein, may be any automatic or manual systems that may be used to enhance robot performance. Exemplary robot systems include a motor system, an autonomous driving system, an electronic stability control system, an anti-lock brake system, a brake assist system, an automatic brake prefill system, a low speed follow system, a cruise control system, a collision warning system, a collision mitigation braking system, an auto cruise control system, a lane departure warning system, a blind spot indicator system, a lane keep assist system, a navigation system, a transmission system, brake pedal systems, an electronic power steering system, visual devices (e.g., camera systems, proximity sensor systems), a climate control system, an electronic pretensioning system, a monitoring system, a passenger detection system, a suspension system, an audio system, a sensory system, among others.

An “agent”, as used herein, may be a machine that moves through or manipulates an environment. Exemplary agents may include robots, vehicles, or other self-propelled machines. The agent may be autonomously, semi-autonomously, or manually operated.

According to one aspect, non-human characters may learn interactions from human demonstrations by extracting the essence of human motion data. The approach discussed herein may be referred to as cross-morphology imitation (CMI), which extends learning from demonstration (LfD) with motion retargeting to learn skills from significantly different morphologies. A framework that enables characters, even those with significantly different morphology from humans, to learn interaction behaviors from human demonstrations is provided herein. The framework includes an interaction embedder and an interaction transferrer.

The interaction embedder may learn a low-dimensional representation, (e.g., an embedded interaction graph), from a trajectory of given interaction movement demonstrations. This embedded interaction graph captures the semantics of the interaction, as it allows the prediction of a character's future pose given the character's current pose and the current embedded graph. The interaction transferrer may utilize the learned embedded interaction graph to design a reward function that guides the character's policy toward interaction consistency. Besides the interaction consistency reward, the interaction transferrer may include a pose correspondence reward to enhance motion diversity and incorporate pre-trained motion primitives to increase training efficiency and motion quality.

Generally, each character with its own distinctive sensory and actuation spaces may have a special, individual policy to imitate the given interaction demonstration, as the policy takes both characters' states as input. Consequently, the input space varies across different character morphologies, each with its own unique state space. This suggests a potential research direction of developing a generalizable, opponent-agnostic interaction policy. Such a policy would allow characters to dynamically adjust their behaviors based on their opponent's physical form. Achieving this goal could involve identifying a unified observation space that encompasses character settings, enabling the benefit of a more flexible and adaptable approach to interaction learning.

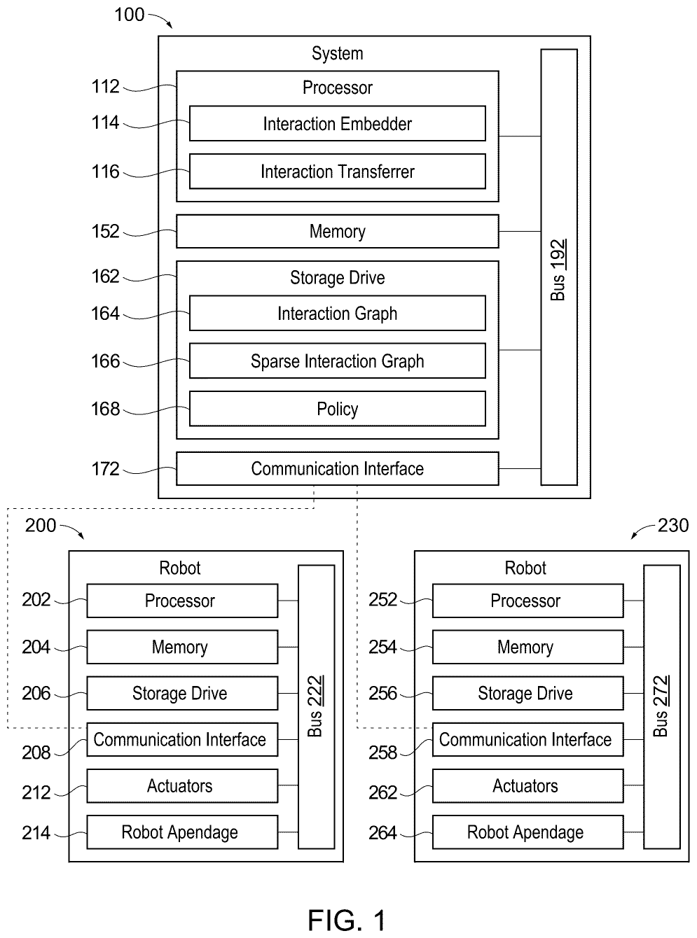

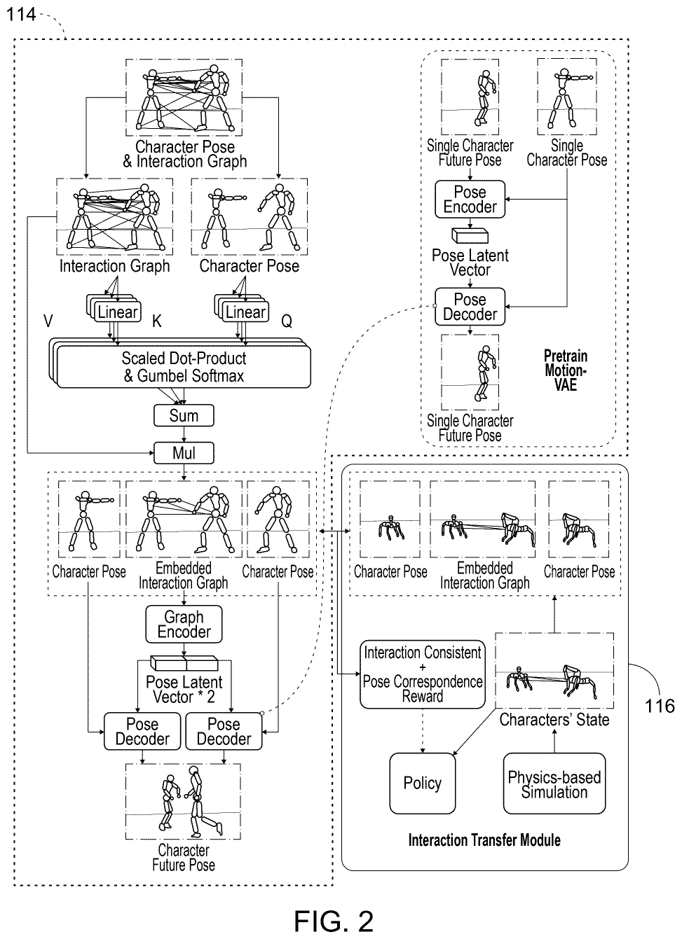

FIG. 1 is described in conjunction with and with reference to FIG. 2. FIG. 1 is an exemplary component diagram of a system 100 for learning physics-based interactions from demonstration, according to one aspect. FIG. 2 is an exemplary scenario associated with learning physics-based interactions from demonstration, according to one aspect.

The system 100 for learning physics-based interactions from demonstration may include a processor 112. The processor 112 may include an interaction embedder 114 and an interaction transferrer 116. The system 100 for learning physics-based interactions from demonstration may include a memory 152 and a storage drive 162. The storage drive 162 may store an interaction graph 164, a sparse interaction graph 166, and a policy 168. The system 100 for learning physics- based interactions from demonstration may include a communication interface 172. The components of the system 100 for learning physics-based interactions from demonstration may be operably connected via a bus 192 and in computer communication with one another. The memory 152 may store one or more instructions. The processor 112 may execute one or more of the instructions stored on the memory 152 to perform one or more acts, actions, and/or steps.

### Interaction Embedder

The interaction embedder 114 may be implemented via the processor 112, the memory 152, and/or the storage drive 162. The processor 112, via the interaction embedder 114, may learn a sparse embedded interaction graph from a fully connected graph indicative of an interaction between a first character and a second character based on cross attention between a pose and a current interaction graph. Explained another way, the interaction embedder 114 may learn one or more embedded features of interactions from human demonstrations. In this way, the interaction embedder 114 may learn a sparse graph representation that effectively captures the interaction demonstration.

The fully connected graph may be indicative of a first pose associated with

the first character and a second pose associated with the second character. The current interaction graph may be derived from the fully connected graph. The fully connected graph, any current interaction graphs, and the learned sparse embedded interaction graph may be stored on the storage drive 162.

Beyond interaction transfer, the learning framework provided herein has broader potential applications, benefits, and advantages which may be achieved by leveraging the learned sparse interaction graph. For example, the learned interaction embedder 114 may be used independently for motion prediction in various contexts, such as computer games or sports analysis, without the interaction transferrer 116. By efficiently capturing components of interactive motions, the embedding may improve prediction accuracy in challenging scenarios, such as humans interacting with objects or other players. Another possible application is social behavior analysis across multiple users or characters. The learned embedded graph, which explicitly highlights core relationships between characters, may be used to infer underlying motivations and intentions in human interactions. Analyzing these relationships could provide deeper insights into social dynamics, improve human robot interactions, and enhance the realism of virtual characters in simulations and entertainment.

The goal of the interaction embedder 114 is to learn a low-dimensional representation of interaction movements demonstrated, facilitating easier transfer to new character settings. The interaction embedder 114 utilizes the interaction graph Φ to model the demonstrated movements. One challenge addressed is transforming the original, fully connected interaction graph into a sparser version (e.g., a sparse embedded interaction graph), Φ^{emb}, which maintains interaction details while reducing complexity. The learning process may include the pre-training of a human motion decoder and the development of the embedded interaction graph.

The interaction embedder 114 may learn the sparse graph representation to model complex human interaction movement. The embedded interaction graph models how one character's pose is influenced by another character. Given the sparse graph representation, a character's future movement may be accurately predicted using the interaction embedder 114. The learned sparse graph may capture the core features of the interaction which trigger the future actions of characters. Thus, the learned embedded graph may be utilized as anchor knowledge for transferring interaction to a new character's setting. The interaction embedder 114 may learn a low-dimensional, sparse graph representation to capture the information of interaction demonstrations, which applies to a wider range of morphologies.

The learned embedded graphs may reveal how characters future interaction movement is determined by a current character state. According to one aspect, the vertices in the embedded graph are on the character's arms and root.

In the interaction embedder 114, the interaction demonstration dataset [symbol] may include various human interaction scenarios. Each interaction trajectory

$${τ}^{d e m o} = \{ ( {\hat{q}}_{t}^{0} , … , {\hat{q}}_{t}^{N} ) \}$$

represents a sequence of poses for the characters involved. This dataset may be sourced from motion capture data of real-life actors or from artist-authored keyframe animations. The specific embedded interaction features, named as the embedded interaction graph

$${Φ}_{t}^{e m b} ,$$

which capture the semantic of the interaction are derived from an interaction sequence τ^{demo} by learning a low-dimensional representation to predict future states of the characters.

### Interaction Transferrer

These embedded features are then used in the interaction transferrer 116 to train control policies that recreate the demonstrated interactions in new character configurations. In the interaction transferrer 116, a policy

$$π ( {a}_{t}^{0} , … , {a}_{t}^{j} \vert {s}_{t}^{0} , … , {s}_{t}^{N} )$$

maps the state of each character to the distribution of actions of each character. These actions may determine target positions for proportional-derivative (PD) controllers or other controller at each joint, which may generate the control torques for motion.

To preserve the semantic of interaction movement, the interaction transferrer 116 uses an interaction consistency reward

$${r}_{t}^{i c} = {r}^{i c} ( {s}_{t}^{0} , … , {s}_{t}^{N} , {Φ}_{c}^{e m b} )$$

according to the character's current state and referenced embedded features acquired from the interaction embedder 114. The interaction consistency reward guides the policy to control characters state where the embedded features may be aligned with demonstrations. In addition to the interaction consistency reward, the interaction transferrer 116 may include a pose correspondence reward

$${r}_{t}^{p c}$$

which strengthens the correspondence between demonstration and target character in the pose level, a regularization reward

$${r}_{t}^{r e g}$$

which refines the quality of the movement.

The processor 112 may generate a pose latent vector based on passing the sparse embedded interaction graph through a graph encoder. The processor 112 may generate a future interaction state for the first character and the second character based on passing the pose latent vector and a first pose associated with the first character through a pose decoder and passing the pose latent vector and a second pose associated with the second character through a second pose decoder. The pose decoder or the second pose decoder may be trained based on a pre-trained motion variable autoencoder (VAE).

The interaction transferrer 116 may be implemented via the processor 112, the memory 152, and/or the storage drive 162. The processor 112 may train, via the interaction transferrer 116, a policy for controlling interactions between the first character and the second character based on using the sparse embedded interaction graph as a reward. Explained another way, the interaction transferrer 116 may use the learned interaction features from the interaction embedder 114 or the sparse embedded interaction graph to guide the training of new characters in a physics-based simulation. The policy may be trained based on the physics-based simulation. In this way, the interaction transferrer 116 may transfer each interaction behavior to new character settings while preserving its semantic meaning. The interaction transferrer 116 may thus leverage the learned embedded graph as a reward signal and train characters to replicate these interactions.

### Reinforcement Learning (RL)

The policy may be stored on the storage drive 162 and may be trained based on a reinforcement learning (RL) approach. In the RL approach, the control policy in the interaction transferrer 116 is trained using a single-agent, model-free reinforcement learning framework. This method involves controlling multiple characters simultaneously with one policy to interact with the environment. At each time step, a meta-agent, or the interaction transferrer 116 may observe a combined state

$${s}_{t}^{meta} = [ {s}_{t}^{0} , ⋯ , {s}_{t}^{j} ]$$

that includes the states of the individual characters. The interaction transferrer 116 may sample a combined action

$${a}_{t}^{meta} = [ {a}_{t}^{0} , ⋯ , {a}_{t}^{j} ]$$

from the policy

$${a}_{t}^{meta} ∼ π ( {a}_{t}^{meta} \vert {s}_{t}^{meta} ) .$$

These actions are applied in the environment, leading to a new combined state

$${s}_{t + 1}^{meta}$$

and a scalar reward

$${r}_{t} = ( {s}_{t}^{meta} , {a}_{t}^{meta} , {s}_{t + 1}^{meta} ) .$$

The goal of this reinforcement learning model is to train a policy that maximizes the expected discounted reward over time:

$$J ( π ) = {p ( τ \vert π )}_{} [ {\sum }_{t = 0}^{T - 1} {γ}^{t} {r}_{t} ] \qquad ( 1 )$$

where τ represents the trajectory sampled by executing the policy π in the environment, T denotes the total horizon of the trajectory, and γ ∈ [0, 1) is the discount factor.

### Interaction Graph

To capture the semantics of interactions between characters during motion, the interaction graph representation may be utilized. This graph-based spatial descriptor encapsulates interaction data within its edges and vertices. Construction of the interaction graph may occur by placing markers on each character. Markers may be placed on each joint of each character, thereby serving as nodes in the graph. Edges between these nodes represent connections between pairs of nodes, and each edge is assigned a feature vector eₘₙ ∈ [symbol] , which contains the relative position and middle point position of the connected nodes. By knowing the pose of a single character and the interaction graph Φₜ, the entire interaction scene may be reconstructed using inverse kinematics

$$( {\hat{q}}_{t}^{0} , ⋯ , {\hat{q}}_{t}^{N} ) = IK ( {\hat{q}}_{t}^{j} , {Φ}_{t} ) .$$

### Problem Formulation

The processor 112 may model the interaction movement as a Markov Decision Process, where the future pose of each character is solely dependent on their current state, formulated as:

$$P ( {\hat{q}}_{t + 1}^{0} , ⋯ , {\hat{q}}_{t + 1}^{j} \vert {\hat{q}}_{t}^{0} , ⋯ , {\hat{q}}_{t}^{j} ) = {\prod }_{j = 0}^{N} P ( {\hat{q}}_{t + 1}^{j} \vert {\hat{q}}_{t}^{0} , ⋯ , {\hat{q}}_{t}^{j} ) \qquad ( 2 )$$

By leveraging the kinematic equivalence, this may be simplified to

$$P ( {\hat{q}}_{t + 1}^{j} \vert {\hat{q}}_{t}^{j} , {Φ}_{t} ) .$$

The interaction embedder 114's objective is to learn a sparse embedded interaction graph Φₜ^{emb}that may effectively replace the original, fully connected graph Φₜ to describe the interaction. Hence, the problem may be defined by the processor 112 as:

$${arg min}_{{Φ}_{t}^{emb} , G} {{( {\hat{q}}_{t + 1}^{j} , {\hat{q}}_{t}^{j} , {Φ}_{t} )}_{}}_{∼ D} ‖ {\hat{q}}_{t + 1}^{j} - G ( {\hat{q}}_{t}^{j} , {Φ}_{t}^{emb} ) ‖ \qquad ( 3 )$$

$$s . t ( {Φ}_{t}^{emb} ) \leq k , {Φ}_{t}^{emb} ∈ {Φ}_{t} \qquad ( 4 )$$

Here,

$$( {Φ}_{t}^{emb} ) \leq k$$

indicates the total number of edges in the embedded graph should be less than a predefined threshold number k. G is a human motion generator trained along with the embedded graph.

### Pretrain Human Motion Generative Model

Learning interactions is a challenging problem that involves multiple high-dimensional poses. A human motion generative model may be pretrained, which may generate diverse human motions from compact latent vectors. This model takes current proprioceptive data of a human and a latent vector as inputs. It may be noted that this generative model predicts the pose of a single human, rather than the poses of the characters in the scene. The same model may be employed for each humanoid character within the scene to predict the overall future interaction state.

The motion embedding model may be built upon a Motion Variational Autoencoder (MVAE) framework. This model uses the character's current pose and a latent variable

$${z}_{t}^{VAE} ,$$

which represents potential transitions from the current pose, to reconstruct the subsequent pose. The MVAE is designed to organize the latent space into a normal distribution. In practical applications, only the decoder is utilized during runtime or during an execution phase. The MVAE may take the character's current pose and the latent variable

$${z}_{t}^{VAE}$$

as inputs, outputting the next pose. This predicted pose may then be recursively used as the input to generate a continuous sequence of poses autoregressively.

The framework may adopt the network architecture and general training approach of the MVAE, implementing several strategies to ensure successful training on reconstructed motions. To enhance the stability of autoregressive predictions, scheduled sampling may be employed. The coefficient β may be tuned for the KL divergence loss. A large β may result in the decoder disregarding the latent variable

$${z}_{t}^{VAE}$$

and merely reproducing the original motion data, while a small β may cause the MVAE to overgeneralize, leading to unrealistic motions with noticeable artifacts, such as body shaking and foot skating. Therefore, a β value of 0.3 may be utilized to strike an optimal balance between flexibility and motion quality in the learned motion embedding.

### Learning Embedded Interaction Graph

With the human motion generative model established, the next goal is to learn an embedded interaction graph. This graph must contain enough information to accurately map to the appropriate latent variable in the pretrained Motion VAE's space, allowing for the correct reconstruction of future poses, with a limited number of edges. For each interaction scenario, the interaction embedder 114 may be trained, but the same MVAE decoder may be employed across scenarios for pose reconstruction.

The learning structure is illustrated in FIG. 2. This pipeline incorporates a multi-head cross-attention mechanism to select useful edges from a fully connected graph, thus forming a sparse graph. The cross attention may be between the first pose of the first character or the second pose of the second character and the current interaction graph. Additionally, an encoding network projects the extracted graph into the latent space of the pretrained MAVE. Specifically, implement hard attention to isolate edges in the graph, ensuring that one edge remains within each head's channel. The attention mechanism evaluates the correspondence between a character's current pose

$${\hat{q}}_{t}^{j}$$

and the current interaction graph

$${Φ}_{t}^{e m b} .$$

Here, the query vector may include the character's pose encoded in a latent space, and the vector is the complete interaction graph, with each edge encoded into a different latent space. Conversely, the value vector comprises the unencoded interaction graph. This design choice (e.g., to avoid encoding the value term) aims to preserve the semantic clarity and interpretability of the resulting embedded interaction graph. This is useful, as it allows the graph to be explicitly used for designing reward functions in new character settings. The filtered interaction graph is then concatenated into a single vector and projected into the MVAE's latent space to facilitate pose reconstruction.

The training process is designed to minimize the error in predicting future poses based on the character's current pose and the current interaction graph. Beyond the standard reconstruction loss, a consistency loss that relies on the variance of the outputs from the attention mechanism may be incorporated.

$${L}_{v a r} = V ar ( Gumbel\_Softmax ( Q {K}^{T} ) ) \qquad ( 5 )$$

### Interaction Transferrer

The interaction transferrer 116 is tasked with transferring interaction movement demonstrations to new character settings while maintaining interaction consistency. The principal challenge here is establishing movement correspondence between demonstrated human movements and those of new characters. The approach may include formulating a cross-domain-transfer-specialized reward and using reinforcement learning to simultaneously learn new character movements and their correspondence to human motion. Instead of focusing on single character movements, the method extends to multi-character scenarios, ensuring the preservation of interaction semantics. Therefore, beside the pose correspondence r^{pc} and regularization reward r^{reg}, an interaction consistency reward r^{ic} may be generated based on the learned embedded graph acquired from the interaction embedder 114 for interaction preservation. The total reward function is the weighted sum of the rewards:

$${r}_{t} = {w}^{i c} {r}_{t}^{i c} + {w}^{p c} {r}^{p c} + {w}^{r e g} {r}^{r e g} \qquad ( 6 )$$

where w^{ic}, w^{pc}, w^{reg} represent the corresponding weight of each reward. The design of the reward functions used to train character control policy and the policy structure that enhances training efficiency is discussed herein.

### Interaction Consistency Reward

The interaction consistency reward is designed to guide the policy toward interaction semantic preservation by measuring the difference between the embedded graph of target characters

$${\overline{Φ}}_{t}^{emb}$$

and

$${Φ}_{t}^{e m b}$$

reference

$${r}_{t}^{i c} ∝ Dis ( {Φ}_{t}^{e m b} , {\overline{Φ}}_{t}^{e m b} ) \qquad ( 7 )$$

where D is indicates distance metrics.

To formulate the distance metrics, the embedded graph in new character setting

$${\overline{Φ}}_{t}^{emb}$$

may be generated from the fully connected graph. This involves vertices selection from markers on new characters. While manual assignment of vertices is feasible due to the limited number of edges and vertices in the embedded graph, an automated vertices assigning mechanism may be implemented. This process involves measuring the overlap between the normalized operational space of vertices in the embedded graph and each vertex's operational space in the new character. Vertex correspondence is determined by the greatest overlap. To measure the overlap, poses of characters may be randomly sampled to get the positional distribution of each vertex. The overlap score may be defined as the KL divergence between the vertex in the referenced embedded graph and on a current character. In cases of identical overlap scores, a pose correspondence reward may be computed for each potential match and the correspondence yielding the higher reward may be selected.

After adapting the embedded graph to the new character settings, the embedded graph may be employed to measure the graph distance using three metrics: length metrics d^{l}, root edge direction metrics d^{ed}, and center point metrics d^{cp}.

The length metrics d^{l} assess the normalized length differences between the edges in the embedded graph of the new setting and the referenced graph:

$${d}_{t}^{l} = {\sum }_{m = 0}^{M - 1} \vert \frac{l ( {e}_{t}^{m} )}{{L}^{c u r}} - \frac{l ( {\hat{e}}_{t}^{m} )}{{L}^{ref}} \vert \qquad ( 8 )$$

Here, M indicates the total number of edges in the referenced embedded graph at time instance t.

$$l ( {e}_{t}^{m} ) and l ( {\hat{e}}_{t}^{m} )$$

represent the length of the m-th edge in the current and referenced graphs, respectively. L^{cur} and L^{ref} are morphology-dependent length values used for normalization.

The root edge direction metrics d^{ed} measure the alignment of the root connection edge's direction in the XY-plane:

$${d}_{t}^{e d} = \frac{〈 {( {e}_{t}^{0} )}_{xy} , {( {\hat{e}}_{t}^{0} )}_{x y} 〉}{l ( {e}_{t}^{0} ) \cdot l ( {\hat{e}}_{t}^{0} )} \qquad ( 9 )$$

Here,

$${( {e}_{t}^{0} )}_{x y}$$

denotes the root connection edge vector projected onto the XY plane.

The center point metrics d^{cp} aim to align the height of the center point of each edge to a reference height:

$${d}_{t}^{cp} = {\sum }_{m = 0}^{M - 1} \vert \frac{h ( {e}_{t}^{m} )}{{L}^{c u r}} - \frac{h ( {\hat{e}}_{t}^{m} )}{{L}^{ref}} \vert \qquad ( 10 )$$

Here, h(eₜ^{m}) and h(êₜ^{m}) denote the center point height of the m-th edge in the current and referenced graphs, respectively.

The framework may employ a multiplicative approach to calculate the interaction consistency reward, addressing the components of the reward simultaneously. To mitigate the issue of low reward values when the current state deviates significantly from the reference, an additional term that considers the length metric dₜ^{l} to handle large discrepancies may be included. The interaction consistency reward may be formulated as follows:

$${r}_{t}^{i c} = 0.9 \times exp ( - {w}^{l} {d}_{t}^{l} ) exp ( - {w}^{e d} {d}_{t}^{e d} ) exp ( - {w}^{cp} {d}_{t}^{cp} ) + 0.1 \times exp ( - {w}^{far} {d}_{t}^{l} ) \qquad ( 11 )$$

Here, w^{l}, w^{ed}, w^{cp}, and w^{far} represent the weights assigned to each component of the reward. The weight w^{far} is set significantly lower than w^{l}, w^{ed}, and w^{cp} to prevent the overall reward value from becoming too small, which may affect the learning algorithm's effectiveness.

This consistency loss may influence the results in two ways. First, it promotes temporal consistency, ensuring that the embedded graph remains stable throughout the trajectory. Additionally, it helps to reduce the number of edges in the learned graph by allowing different heads in the attention mechanism to retain the same edge, thus minimizing redundancy. During training, the activation of the edge that connects to the character's root may be consistently maintained, ensuring structural connections are preserved.

Additionally, the processor 112 may implement the policy to control an interaction between a first robot 200 and a second robot 230 via the communication interface 172. The system 100 for learning physics-based interactions from demonstration may train the policy to operate a first robot 200 and a second robot 230. The first robot 200 may include a processor 202, a memory 204, a storage drive 206, a communication interface 208, one or more actuators 212, a robot appendage 214, and a bus 222 operably connecting respective components to enable computer communication therebetween. The second robot 230 may include a processor 252, a memory 254, a storage drive 256, a communication interface 258, one or more actuators 262, a robot appendage 264, and a bus 272 operably connecting respective components to enable computer communication therebetween.

According to one aspect, the communication interface 172 of the system 100 for learning physics-based interactions from demonstration may transmit commands to the communication interface 208 of the first robot 200 and the communication interface 258 of the second robot 230 which are generated based on the policy 168. The communication interface 208 of the first robot 200 and the communication interface 258 of the second robot 230 may receive the respective commands and implement the commands via the actuators 212, 262 and robot appendages 214, 264. According to one aspect, the policy 168 may be transmitted to the first robot 200 and/or the second robot 230 and the respective robots 200, 230 may generate commands based on the locally stored policy (e.g., stored on the respective storage drives 206, 256).

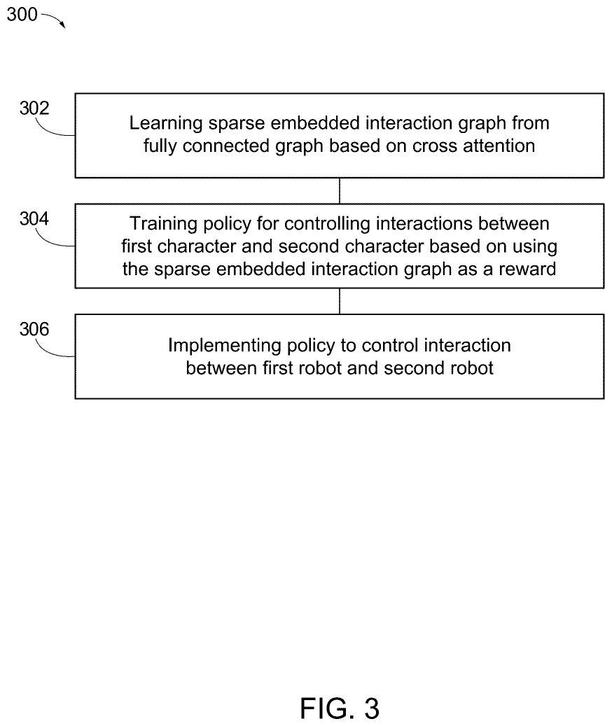

FIG. 3 is an exemplary flow diagram of a computer-implemented method 300 for learning physics-based interactions from demonstration, according to one aspect. The computer-implemented method 300 for learning physics-based interactions from demonstration may include learning 302 a sparse embedded interaction graph from a fully connected graph indicative of an interaction between a first character and a second character based on cross attention between a pose and a current interaction graph, training 304 a policy for controlling interactions between the first character and the second character based on using the sparse embedded interaction graph as a reward, and implementing 306 the policy to control an interaction between a first robot and a second robot.

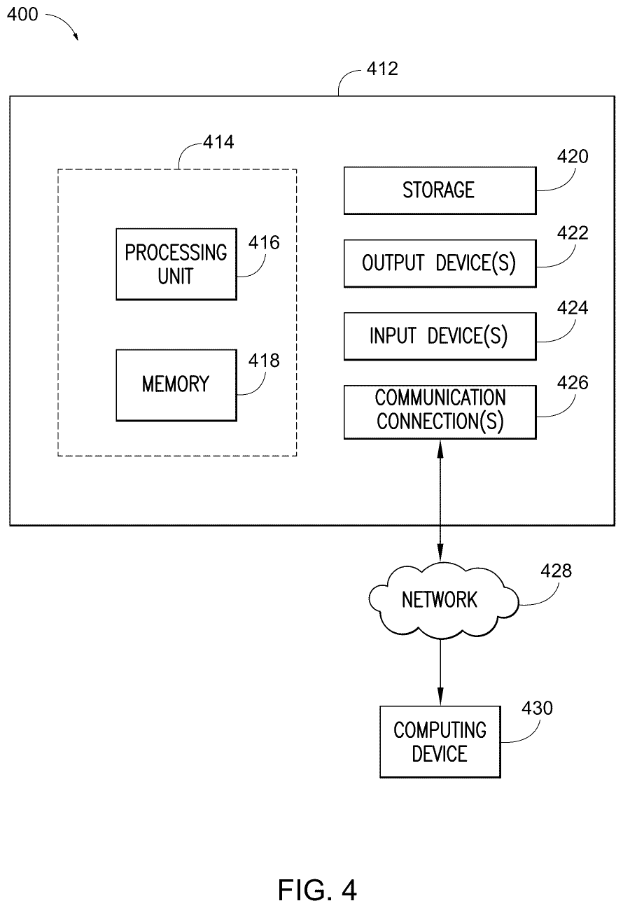

FIG. 4 and the following discussion provide a description of a suitable computing environment to implement aspects of one or more of the provisions set forth herein. The operating environment of FIG. 4 is merely one example of a suitable operating environment and is not intended to suggest any limitation as to the scope of use or functionality of the operating environment. Example computing devices include, but are not limited to, personal computers, server computers, hand-held or laptop devices, mobile devices, such as mobile phones, Personal Digital Assistants (PDAs), media players, and the like, multiprocessor systems, consumer electronics, mini computers, mainframe computers, distributed computing environments that include any of the above systems or devices, etc.

Generally, aspects are described in the general context of “computer readable instructions” being executed by one or more computing devices. Computer readable instructions may be distributed via computer readable media as will be discussed below. Computer readable instructions may be implemented as program modules, such as functions, objects, Application Programming Interfaces (APIs), data structures, and the like, that perform one or more tasks or implement one or more abstract data types. Typically, the functionality of the computer readable instructions are combined or distributed as desired in various environments.

FIG. 4 illustrates a system 400 including a computing device 412 configured to implement one aspect provided herein. In one configuration, the computing device 412 includes at least one processing unit 416 and memory 418. Depending on the exact configuration and type of computing device, memory 418 may be volatile, such as RAM, non-volatile, such as ROM, flash memory, etc., or a combination of the two. This configuration is illustrated in FIG. 4 by dashed line 414.

In other aspects, the computing device 412 includes additional features or functionality. For example, the computing device 412 may include additional storage such as removable storage or non-removable storage, including, but not limited to, magnetic storage, optical storage, etc. Such additional storage is illustrated in FIG. 4 by storage 420. In one aspect, computer readable instructions to implement one aspect provided herein are in storage 420. Storage 420 may store other computer readable instructions to implement an operating system, an application program, etc. Computer readable instructions may be loaded in memory 418 for execution by the at least one processing unit 416, for example.

The term “computer readable media” as used herein includes computer storage media. Computer storage media includes volatile and nonvolatile, removable, and non-removable media implemented in any method or technology for storage of information such as computer readable instructions or other data. Memory 418 and storage 420 are examples of computer storage media. Computer storage media includes, but is not limited to, RAM, ROM, EEPROM, flash memory or other memory technology, CD-ROM, Digital Versatile Disks (DVDs) or other optical storage, magnetic cassettes, magnetic tape, magnetic disk storage or other magnetic storage devices, or any other medium which may be used to store the desired information and which may be accessed by the computing device 412. Any such computer storage media is part of the computing device 412.

The term “computer readable media” includes communication media. Communication media typically embodies computer readable instructions or other data in a “modulated data signal” such as a carrier wave or other transport mechanism and includes any information delivery media. The term “modulated data signal” includes a signal that has one or more of its characteristics set or changed in such a manner as to encode information in the signal.

The computing device 412 includes input device(s) 424 such as keyboard, mouse, pen, voice input device, touch input device, infrared cameras, video input devices, or any other input device. Output device(s) 422 such as one or more displays, speakers, printers, or any other output device may be included with the computing device 412. Input device(s) 424 and output device(s) 422 may be connected to the computing device 412 via a wired connection, wireless connection, or any combination thereof. In one aspect, an input device or an output device from another computing device may be used as input device(s) 424 or output device(s) 422 for the computing device 412. The computing device 412 may include communication connection(s) 426 to facilitate communications with one or more other devices 430, such as through network 428, for example.

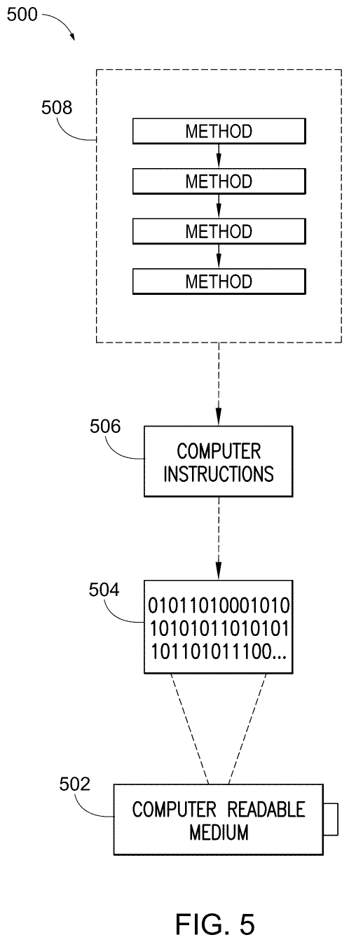

Still another aspect involves a computer-readable medium including processor-executable instructions configured to implement one aspect of the techniques presented herein. An aspect of a computer-readable medium or a computer-readable device devised in these ways is illustrated in FIG. 5, wherein an implementation 500 includes a computer-readable medium 502, such as a CD-R, DVD-R, flash drive, a platter of a hard disk drive, etc., on which is encoded computer-readable data 504. This encoded computer-readable data 504, such as binary data including a plurality of zero's and one's as shown in 504, in turn includes a set of processor-executable computer instructions 506 configured to operate according to one or more of the principles set forth herein. In this implementation 500, the processor-executable computer instructions 506 may be configured to perform a method 508, such as the computer-implemented method 300 for learning physics-based interactions from demonstration of FIG. 3. In another aspect, the processor-executable computer instructions 506 may be configured to implement a system, such as the system 100 for learning physics-based interactions from demonstration of FIG. 1. Many such computer-readable media may be devised by those of ordinary skill in the art that are configured to operate in accordance with the techniques presented herein.

As used in this application, the terms “component”, “module,” “system”, “interface”, and the like are generally intended to refer to a computer-related entity, either hardware, a combination of hardware and software, software, or software in execution. For example, a component may be, but is not limited to being, a process running on a processor, a processing unit, an object, an executable, a thread of execution, a program, or a computer. By way of illustration, both an application running on a controller and the controller may be a component. One or more components residing within a process or thread of execution and a component may be localized on one computer or distributed between two or more computers.

Further, the claimed subject matter is implemented as a method, apparatus, or article of manufacture using standard programming or engineering techniques to produce software, firmware, hardware, or any combination thereof to control a computer to implement the disclosed subject matter. The term “article of manufacture” as used herein is intended to encompass a computer program accessible from any computer-readable device, carrier, or media. Of course, many modifications may be made to this configuration without departing from the scope or spirit of the claimed subject matter.

Although the subject matter has been described in language specific to structural features or methodological acts, it is to be understood that the subject matter of the appended claims is not necessarily limited to the specific features or acts described above. Rather, the specific features and acts described above are disclosed as example aspects.

Various operations of aspects are provided herein. The order in which one or more or all of the operations are described should not be construed as to imply that these operations are necessarily order dependent. Alternative ordering will be appreciated based on this description. Further, not all operations may necessarily be present in each aspect provided herein.

As used in this application, “or” is intended to mean an inclusive “or” rather than an exclusive “or”. Further, an inclusive “or” may include any combination thereof (e.g., A, B, or any combination thereof). In addition, “a” and “an” as used in this application are generally construed to mean “one or more” unless specified otherwise or clear from context to be directed to a singular form. Additionally, at least one of A and B and/or the like generally means A or B or both A and B. Further, to the extent that “includes”, “having”, “has”, “with”, or variants thereof are used in either the detailed description or the claims, such terms are intended to be inclusive in a manner similar to the term “comprising”.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that various of the above-disclosed and other features and functions, or alternatives or varieties thereof, may be desirably combined into many other different systems or applications. Also, that various presently unforeseen or unanticipated alternatives, modifications, variations, or improvements therein may be subsequently made by those skilled in the art which are also intended to be encompassed by the following claims.

1. A system for learning physics-based interactions from demonstration, comprising:
a memory storing one or more instructions; and
a processor executing one or more of the instructions stored on the memory to perform:
learning a sparse embedded interaction graph from a fully connected graph indicative of an interaction between a first character and a second character based on cross attention between a pose and a current interaction graph; and
training a policy for controlling interactions between the first character and the second character based on using the sparse embedded interaction graph as a reward.

2. The system for learning physics-based interactions from demonstration of claim 1, wherein the processor implements the policy to control an interaction between a first robot and a second robot.

3. The system for learning physics-based interactions from demonstration of claim 1, wherein the fully connected graph is indicative of a first pose associated with the first character and a second pose associated with the second character.

4. The system for learning physics-based interactions from demonstration of claim 3, wherein the cross attention is between the first pose of the first character or the second pose of the second character and the current interaction graph.

5. The system for learning physics-based interactions from demonstration of claim 1, wherein the current interaction graph is derived from the fully connected graph.

6. The system for learning physics-based interactions from demonstration of claim 1, wherein the processor generates a pose latent vector based on passing the sparse embedded interaction graph through a graph encoder.

7. The system for learning physics-based interactions from demonstration of claim 6, wherein the processor generates a future interaction state for the first character and the second character based on passing the pose latent vector and a first pose associated with the first character through a pose decoder and passing the pose latent vector and a second pose associated with the second character through a second pose decoder.

8. The system for learning physics-based interactions from demonstration of claim 7, wherein the pose decoder is trained based on a pre-trained motion variable autoencoder (VAE).

9. The system for learning physics-based interactions from demonstration of claim 1, wherein training the policy is based on a reinforcement learning approach.

10. The system for learning physics-based interactions from demonstration of claim 1, wherein training the policy is based on a physics-based simulation.

11. A computer-implemented method for learning physics-based interactions from demonstration, comprising:
learning a sparse embedded interaction graph from a fully connected graph indicative of an interaction between a first character and a second character based on cross attention between a pose and a current interaction graph; and
training a policy for controlling interactions between the first character and the second character based on using the sparse embedded interaction graph as a reward.

12. The computer-implemented method for learning physics-based interactions from demonstration of claim 11, comprising implementing the policy to control an interaction between a first robot and a second robot.

13. The computer-implemented method for learning physics-based interactions from demonstration of claim 11, wherein the fully connected graph is indicative of a first pose associated with the first character and a second pose associated with the second character.

14. The computer-implemented method for learning physics-based interactions from demonstration of claim 13, wherein the cross attention is between the first pose of the first character or the second pose of the second character and the current interaction graph.

15. The computer-implemented method for learning physics-based interactions from demonstration of claim 11, comprising deriving the current interaction graph from the fully connected graph.

16. A system for learning physics-based interactions from demonstration, comprising:
a memory storing one or more instructions; and
a processor executing one or more of the instructions stored on the memory to perform:
learning a sparse embedded interaction graph from a fully connected graph indicative of an interaction between a first character and a second character based on cross attention between a pose of the first character or a pose of the second character and a current interaction graph;
training a policy for controlling interactions between the first character and the second character based on using the sparse embedded interaction graph as a reward; and
implementing the policy to control an interaction between a first robot and a second robot.

17. The system for learning physics-based interactions from demonstration of claim 16, wherein the fully connected graph is indicative of a first pose associated with the first character and a second pose associated with the second character.

18. The system for learning physics-based interactions from demonstration of claim 17, wherein the cross attention is between the first pose of the first character or the second pose of the second character and the current interaction graph.

19. The system for learning physics-based interactions from demonstration of claim 16, wherein the current interaction graph is derived from the fully connected graph.

20. The system for learning physics-based interactions from demonstration of claim 16, wherein the processor generates a pose latent vector based on passing the sparse embedded interaction graph through a graph encoder.
